(19) United States
(12) Patent Application Publication
(10) Pub. No.: US 2026/0062649 A1
(43) Pub. Date: Mar. 5, 2026

(54) POST-CMP CLEANING COMPOSITION AND POST-CMP CLEANING METHOD

(71) Applicant: FUJIMI INCORPORATED, Aichi (JP)

(72) Inventors: Keita Suzuki, Aichi (JP); Yasuyuki Yamato, Aichi (JP); Shota Suzuki, Aichi (JP)

(21) Appl. No.: 19/312,717

(22) Filed: Aug. 28, 2025

(30) Foreign Application Priority Data
Aug. 29, 2024 (JP) 2024-147063

(51) Int. Cl. C11D 3/37; C11D 1/10; C11D 1/12; C11D 1/34; C11D 1/62; C11D 1/66; C11D 1/72; C11D 1/92; C11D 3/22; H01L 21/02

(52) U.S. Cl. CPC C11D 3/3776; C11D 1/10; C11D 1/123; C11D 1/345; C11D 1/62; C11D 1/667; C11D 1/72; C11D 1/92; C11D 3/225; C11D 3/3753

(57) ABSTRACT

There are provided a post-CMP cleaning composition and a post-CMP cleaning method, which can more effectively reduce impurities remaining on a surface of polished objects to be polished. The post-CMP cleaning composition is used for cleaning polished objects to be polished as objects to be polished, which has been subjected to a chemical mechanical polishing (CMP), the post-CMP cleaning composition containing water, a water-soluble polymer, and a surfactant, in which, when a surface of the polished objects to be polished is covered with the post-CMP cleaning composition, in a case where the surface is observed with an atomic force microscope, a restoring adhesion force which is a force acting between a probe of the atomic force microscope, which has a tip radius of curvature of 2 nm or more and 12 nm or less, and the surfactant is more than 0 N/m and 0.07 N/m or less, and a surface roughness of an adsorption layer which is formed by adsorption of the surfactant over the surface of the polished objects to be polished is more than 0 nm and 0.4 nm or less.

### TECHNICAL FIELD

The present invention relates to a post-CMP cleaning composition and a post-CMP cleaning method.

### BACKGROUND ART

In recent years, along with multilayer wiring on a surface of a semiconductor substrate, a so-called chemical mechanical polishing (CMP) art has been utilized to polish and flatten the semiconductor substrate when manufacturing a device. The CMP is a method of flattening a surface of objects to be polished (polishing target) such as the semiconductor substrate, using a polishing composition (slurry) containing abrasives such as silica, alumina, and ceria, an anticorrosive agent, a surfactant, and the like, in which the objects to be polished (polishing target) is for example, silicon, polysilicon, a silicon oxide film (silicon oxide), a silicon nitride, a wiring and a plug consisting a metal, or the like.

A large amount of impurities such as contaminants and residues remain on the surface of the semiconductor substrate after the CMP step. The impurities include abrasives, metals, and organic substances such as an anticorrosive agent and a surfactant derived from a polishing composition used in the CMP, a silicon-containing material derived from the objects to be polished, a silicon-containing material or a metal generated by polishing a wiring, a plug, or the like, and organic substances such as pad debris generated from various pads used for polishing.

When the surface of the semiconductor substrate is contaminated with such impurities, electrical characteristics of the semiconductor deteriorate, and thus reliability of a device using the semiconductor may be reduced. Therefore, it is desirable to introduce a cleaning step after the CMP step to remove the impurities from the surface of the semiconductor substrate. In a post-CMP cleaning composition used for such cleaning after the CMP step, that is, used in post-CMP cleaning, cleaning function is controlled by containing a water-soluble polymer (PTL 1 and PTL 2).

### CITATION LIST

### Patent Literatures

PTL 1: JP 2022-155133 A
PTL 2: JP 2022-155989 A

### SUMMARY

### Technical Problem

However, at the leading edge of semiconductor process nodes, further miniaturization of the surface of the semiconductor substrate is progressing, and the influence of the impurities remaining on the semiconductor substrate is further increased. Therefore, there is a demand for a cleaning composition and a cleaning method, which can more effectively reduce the impurities remaining on the surface of the semiconductor substrate after the CMP polishing.

The present invention has been made in view of such circumstances, and an object of the present invention is to provide a post-CMP cleaning composition and a post-CMP cleaning method, which can more effectively reduce impurities remaining on a surface of polished objects to be polished.

### Solution to Problem

A post-CMP cleaning composition according to one aspect of the present invention is a post-CMP cleaning composition used for cleaning polished objects to be polished as objects to be polished, which has been subjected to a chemical mechanical polishing (CMP), the post-CMP cleaning composition containing water, a water-soluble polymer, and a surfactant, in which, when a surface of the polished objects to be polished is covered with the post-CMP cleaning composition, in a case where the surface is observed with an atomic force microscope, a restoring adhesion force which is a force acting between a probe of the atomic force microscope, which has a tip radius of curvature of 2 nm or more and 12 nm or less, and the surfactant is more than 0 N/m and 0.07 N/m or less, and a surface roughness of an adsorption layer which is formed by adsorption of the surfactant over the surface of the polished objects to be polished is more than 0 nm and 0.4 nm or less.

In addition, a post-CMP cleaning method according to another aspect of the present invention is a post-CMP cleaning method of performing post-CMP cleaning on polished objects to be polished which has a layer containing a silicon-containing material, using the post-CMP cleaning composition according to the one aspect of the present invention, the post-CMP cleaning method including bring a surface of the polished objects to be polished into contact with the post-CMP cleaning composition to form, on the surface of the polished objects to be polished which has the layer containing a silicon-containing material, a surface-treated layer containing the water, the water-soluble polymer, and the surfactant, in which the surface-treated layer has an adsorption layer which is formed by adsorption of the surfactant over the surface of the polished objects to be polished which has the layer containing a silicon-containing material, in a case where the surface-treated layer is observed with an atomic force microscope, a restoring adhesion force which is a force acting between a probe of the atomic force microscope, which has a tip radius of curvature of 2 nm or more and 12 nm or less, and the surfactant in the surface-treated layer is more than 0 N/m and 0.07 N/m or less, and a surface roughness of a surface of the adsorption layer is more than 0 nm and 0.4 nm or less.

### Advantageous Effects

According to the present invention, it is possible to provide a post-CMP cleaning composition and a post-CMP cleaning method, which can more effectively reduce impurities remaining on a surface of polished objects to be polished.

### DESCRIPTION OF EMBODIMENTS

Embodiments of the present invention will be described in detail. The following embodiments show examples of the present invention, but the present invention is not limited to the embodiments. In addition, various changes or enhancements can be added to the following embodiments, and the present invention may also include embodiments to which such changes or enhancements have been added.

### (Post-CMP Cleaning Composition)

The embodiment according to the present invention is a post-CMP cleaning composition used for cleaning polished objects to be polished as objects to be polished, which has been subjected to chemical mechanical polishing (CMP), the post-CMP cleaning composition containing water, a water-soluble polymer, and a surfactant. In addition, when a surface of the polished objects to be polished is covered with the post-CMP cleaning composition according to the present embodiment, in a case where the surface is observed with an atomic force microscope, a restoring adhesion force which is a force acting between a probe of the atomic force microscope, which has a tip radius of curvature of 2 nm or more and 12 nm or less, and the surfactant is more than 0 N/m and 0.07 N/m or less, and a surface roughness of an adsorption layer which is formed by adsorption of the surfactant over the surface of the polished objects to be polished is more than 0 nm and 0.4 nm or less.

The present inventors have found that, by using the post-CMP cleaning composition having the above-described configuration, it is possible to suppress reattachment of a residue which has been released from the surface of the polished objects to be polished, to the surface of the polished objects to be polished, and to facilitate detachment of the surfactant in the post-CMP cleaning composition. Therefore, when the post-CMP cleaning composition according to the present embodiment is used, the residue remaining on the surface of the polished objects to be polished can be effectively removed.

### (Polished Objects to be Polished)

In the present specification, the polished objects to be polished means objects to be polished, which has been polished in a polishing step. The polishing step is a chemical mechanical polishing (CMP) step.

The polished objects to be polished according to the present embodiment may have a layer containing a silicon-containing material. Examples of the silicon-containing material include simple substance of silicon, polycrystalline silicon, and a silicon compound. Examples of the simple substance of silicon include single crystal silicon, polycrystalline silicon (polysilicon), and amorphous silicon. Examples of the silicon compound include silicon nitride (SiN), silicon oxide (SiO₂), silicon carbide (SiC), and silicon germanium (SiGe). The silicon-containing material also includes a low dielectric constant material having a relative permittivity of 3 or less. In addition, the polished objects to be polished according to the embodiment of the present invention also includes n-type impurity-doped polysilicon and p-type impurity-doped polysilicon. These silicon-containing materials may be used alone or in combination of two or more types thereof.

The layer containing a silicon-containing material may contain a material other than the silicon-containing material. Examples of other materials include carbon and a metal. Examples of the metal include tungsten (W), copper (Cu), aluminum (Al), hafnium (Hf), cobalt (Co), nickel (Ni), titanium (Ti), tantalum (Ta), gold (Au), silver (Ag), platinum (Pt), palladium (Pd), rhodium (Rh), ruthenium (Ru), iridium (Ir), and osmium (Os). These metals may be used alone or in combination of two or more types thereof.

### (Residue)

In the present specification, the residue means a contaminant attached to the surface of the polished objects to be polished. The residue is not particularly limited, and examples thereof include an organic residue described later, a particle residue derived from abrasives contained in a polishing composition, a residue consisting of components other than the particle residue and the organic residue, and a mixture of the particle residue and the organic residue. In addition, the organic residue means a component consisting of an organic substance such as an organic low-molecular-weight compound and an organic high-molecular-weight compound, or an organic salt, among contaminants attached to the surface of the polished objects to be polished.

In the present specification, the total number of residues means the total number of all residues regardless of the type. The total number of residues can be measured with a wafer defect inspection device. Details of the method for measuring the number of residues will be described in Examples later.

Examples of the organic residue attached to the polished objects to be polished include pad debris generated from a pad used in the polishing step or the rinse polishing step described later, and various components derived from a polishing composition used in the polishing step or a rinse polishing composition used in the rinse polishing step.

Since the organic residue and the other contaminants are significantly different in color and shape, the determination of whether or not the contaminants are the organic residue can be performed by visual observation with a scanning electron microscope (SEM) or the like, element analysis with an energy dispersive X-ray analysis (EDX) device attached to the scanning electron microscope, or the like. In addition, the measurement of the number of organic residues can be performed not only by the wafer defect inspection device but also by the scanning electron microscope or the energy dispersive X-ray analysis.

### (Restoring Adhesion Force and Surface Roughness)

In the post-CMP cleaning composition according to the present embodiment, when a surface of the polished objects to be polished is covered with the post-CMP cleaning composition, in a case where the surface is observed with an atomic force microscope (AFM), a restoring adhesion force acting between a probe of the atomic force microscope, which has a tip radius of curvature of 2 nm or more and 12 nm or less, and the surfactant is more than 0 N/m and 0.07 N/m or less, and a surface roughness of the surface of the polished objects to be polished covered with the post-CMP cleaning composition is more than 0 nm and 0.4 nm or less.

In a case where the post-CMP cleaning composition and the surface of the polished objects to be polished come into contact with each other, the surface of the polished objects to be polished is covered with the post-CMP cleaning composition. In this case, when the surface of the polished objects to be polished is hydrophilic, the surfactant contained in the post-CMP cleaning composition forms an associate such as micelles such that the hydrophilic group faces a surface side of the polished objects to be polished. In addition, when the surface of the polished objects to be polished is hydrophobic, the surfactant contained in the post-CMP cleaning composition forms an associate such as micelles such that the hydrophobic group faces the surface of the polished objects to be polished. Therefore, an adsorption layer is formed over the surface of the polished objects to be polished by the associate of the surfactant. The surface of the formed adsorption layer has a concave-convex shape according to a shape of the associate of the surfactant.

Between the adsorption layer formed over the surface of the polished objects to be polished in this manner and the residue which is about to approach the surface, a repulsive force such as a zeta potential is generated, and thus the reattachment of the residue is suppressed. A steric repulsive force derived from the water-soluble polymer or the associate of the surfactant, constituting the adsorption layer, acts on the residue which has reached the adsorption layer beyond the repulsive force. Therefore, the steric repulsive force makes it difficult for the residue and the polished objects to be polished to come into direct contact with each other. When the residue compresses the adsorption layer, a decrease in configurational entropy occurs. The steric repulsive force is considered to be generated by an osmotic pressure of the solvent with the decrease in configurational entropy. In addition, the steric repulsive force not only prevents the residue from coming into direct contact with the polished objects to be polished, but also makes it easy for the residue to be released from the vicinity of the surface of the polished objects to be polished. Here, the ease of release of the residue can be measured as an adhesion force using the atomic force microscope. The adhesion force means an adhesion strength between the probe of the atomic force microscope and the water-soluble polymer or the associate of the surfactant, and can be evaluated as a magnitude of a force required for the release of the residue. In order to reduce the adhesion force, it is effective to increase the above-described steric repulsive force or to reduce an intermolecular force between the adsorption layer and the residue.

In general, the adhesion force measured using the atomic force microscope includes influence of a surface shape or a surface viscosity, in addition to the steric repulsive force and the intermolecular force. On the other hand, the restoring adhesion force is a force which strongly reflects the intermolecular force among the adhesion forces which act between the probe of the atomic force microscope and the surfactant, and means an adhesion strength due to the intermolecular force between the probe of the atomic force microscope and the surfactant. By using a material similar to the residue in the tip part of the probe, the probe can be regarded as the residue. Therefore, it can be said that the restoring adhesion force acting between the probe and the surfactant is the adhesion strength acting between the residue and the surfactant. In addition, the surface roughness means an arithmetic average roughness (Ra) of the surface of the adsorption layer formed by the surfactant as described above.

When the restoring adhesion force and the surface roughness are within the above-described ranges, it is considered that the residue is easily released from the surfactant, and the reattachment of the residue to the surface of the polished objects to be polished is suppressed, so that the residue can be sufficiently removed.

The restoring adhesion force may be more than 0 N/m and 0.05 N/m or less, or more than 0 N/m and 0.04 N/m or less. In addition, the surface roughness may be more than 0 nm and less than 0.3 nm, or more than 0 nm and 0.25 nm or less. In such ranges, the residue is more easily released from the surfactant, and thus the residue is more easily removed.

The details of the method of measuring the restoring adhesion force and the surface roughness will be described in Examples later.

### (Surfactant)

The post-CMP cleaning composition according to the one aspect of the present invention contains a surfactant. The type of the surfactant is not particularly limited, and may be at least one of an amphoteric surfactant, a cationic surfactant, a nonionic surfactant, or an anionic surfactant.

Examples of the amphoteric surfactant include lecithin, alkylamine oxide, alkyl betaine such as N-alkyl-N,N-dimethylammonium betaine, and sulphobetaine such as 3-[(3-colamidopropyl)dimethylammonio]-1-propanesulfonic acid and dodecyldimethyl(3-sulfopropyl)ammonium hydroxide.

Examples of the cationic surfactant include amines such as laurylamine hydrochloride, quaternary ammonium salts such as domiphen bromide, decyltrimethylammonium bromide, and benzyldodecyldimethylammonium bromide, and pyridinium salts such as 1-dodecylpyridinium chloride and laurylpyridinium chloride.

Examples of the nonionic surfactant include an alkyl ether type surfactant such as hexaethylene glycol monododecyl ether, polyoxyethylene lauryl ether, and polyoxyethylene oleyl ether; an alkylphenyl ether type surfactant such as polyoxyethylene octylphenyl ether; an alkyl ester type surfactant such as polyoxyethylene laurate; an alkyl amine type surfactant such as polyoxyethylene lauryl amino ether; an alkyl amide type surfactant such as polyoxyethylene lauric acid amide; a polypropylene glycol ether type surfactant such as polyoxyethylene polyoxypropylene ether; an alkanol amide type surfactant such as oleic acid diethanol amide; an allyl phenyl ether type surfactant such as polyoxyalkylene allyl phenyl ether; and a nonylphenyl ether type surfactant such as polyethylene glycol mono-4-nonylphenyl ether. In addition, monopalmitin, propylene glycol, ethylene glycol, monoethanolamine, alcohol ethoxylate, alkylphenol ethoxylate, tertiary acetylene glycol, and the like can also be used as the nonionic surfactant.

Examples of the anionic surfactant include a carboxylic acid type surfactant such as sodium myristate, sodium palmitate, sodium stearate, sodium laurate, and potassium laurate; a sulfuric acid ester type surfactant such as sodium octyl sulfonate; a phosphoric acid ester type surfactant such as sodium monododecyl phosphate, lauryl phosphate, and sodium lauryl phosphate; a sulfonic acid type surfactant such as sodium bis(2-ethylhexyl) sulfosuccinate, sodium dioctyl sulfosuccinate, and sodium dodecylbenzene sulfonate; and an amino acid type surfactant such as N-lauroylsarcosine sodium salt.

The surfactant may be used alone or in combination of two or more types thereof. In addition, as the surfactant, a commercially available product may be used, or a synthetic product may be used.

Among these surfactants, it is preferable to use at least one selected from the group consisting of 3-[(3-cholamidopropyl)dimethylammonio]-1-propanesulfonic acid, dodecyldimethyl(3-sulfopropyl)ammonium hydroxide, domiphen bromide, decyltrimethylammonium bromide, 1-dodecylpyridinium chloride, benzyldodecyl dimethylammonium bromide, hexaethylene glycol monododecyl ether, polyethylene glycol mono-4-nonylphenyl ether, monopalmitin, bis(2-ethylhexyl) sulfosuccinate sodium salt, sodium monododecyl phosphate, and N-lauroylsarcosine sodium salt.

A lower limit value of a concentration of the surfactant in the post-CMP cleaning composition may be 0.01 g/L or more, 0.05 g/L or more, 0.1 g/L or more, or 0.3 g/L or more with respect to the post-CMP cleaning composition. In addition, an upper limit value of the concentration of the surfactant in the post-CMP cleaning composition may be 10 g/L or less, 5 g/L or less, 3 g/L or less, or 1 g/L or less. In such a range, the adhesive force between the surface of the polished objects to be polished and the residue is reduced, so that the total number of residues remaining is likely to be reduced.

When the post-CMP cleaning composition contains two or more types of the surfactants, the content of the surfactant means the total content thereof.

### (Water-Soluble Polymer)

The post-CMP cleaning composition according to the one aspect of the present invention contains a water-soluble polymer. The water-soluble polymer may be a homopolymer or a copolymer, and may be a compound having a weight-average molecular weight (Mw) of 1,000 or more. The type of the water-soluble polymer is not particularly limited, and may be at least one selected from an amphoteric water-soluble polymer, a cationic water-soluble polymer, a nonionic water-soluble polymer, and an anionic water-soluble polymer. In addition, when the water-soluble polymer is a copolymer, the form of the copolymer may be any of a block copolymer, a random copolymer, a graft copolymer, or an alternating copolymer.

Examples of the amphoteric water-soluble polymer include a copolymer of a vinyl monomer having an anionic group and a vinyl monomer having a cationic group, a vinyl-based amphoteric polymer having a carboxybetaine group or a sulfabetaine group; and specific examples thereof include an acrylic acid/dimethylaminoethyl methacrylate copolymer and an acrylic acid/diethylaminoethyl methacrylate copolymer.

Examples of the cationic water-soluble polymer include polyethyleneimine (PEI), polyvinylamine, polyallylamine, polyvinylpyridine, and a polymer of cationic acrylamide.

Examples of the nonionic water-soluble polymer include polyvinyl alcohol (PVA), an ethylene-vinyl alcohol copolymer (EVOH), polyvinylpyrrolidone (PVP), polyacrylamide, poly-N-vinylacetamide (PNVA), polyamines, polyvinyl ethers (polyvinyl methyl ether, polyvinyl ethyl ether, polyvinyl isobutyl ether, and the like), polyglycerin, polyethylene glycol, polypropylene glycol, polysaccharides such as water-soluble cellulose (hydroxyethyl cellulose (HEC), hydroxypropyl cellulose, hydroxyethyl methyl cellulose, hydroxypropyl methyl cellulose, methyl cellulose, ethyl cellulose, and ethyl hydroxyethyl cellulose), alginic acid polyvalent alcohol ester, a water-soluble urea resin, a dextrin derivative, and casein. In addition to those having such a main chain structure, a graft copolymer having a nonionic polymer structure may be used.

Examples of the anionic water-soluble polymer include polyvinylsulfonic acid, polystyrenesulfonic acid, polyallylsulfonic acid, polymethallylsurfonic acid, poly(2-acrylamido-2-methylpropane sulfonic acid), polyisoprenesulfonic acid, polyacrylic acid, and polymethacrylic acid.

As the water-soluble polymer, a copolymer of the water-soluble polymer mentioned above may be used.

The water-soluble polymer may be used alone or in combination of two or more types thereof. In addition, as the water-soluble polymer, a commercially available product may be used, or a synthetic product may be used.

From the viewpoint of easily separating from the polished objects to be polished after the rinse polishing, the water-soluble polymer may be a nonionic water-soluble polymer. As the nonionic water-soluble polymer, polyvinyl alcohol, polyvinylpyrrolidone, or hydroxyethyl cellulose is particularly preferable. That is, the water-soluble polymer may be at least one selected from the group consisting of polyvinyl alcohol, polyvinylpyrrolidone, and hydroxyethyl cellulose.

A lower limit value of a weight-average molecular weight (Mw) of the water-soluble polymer may be 1,000 or more, 1,500 or more, or 2,000 or more. In addition, an upper limit value of the weight-average molecular weight of the water-soluble polymer may be 1,500,000 or less, 1,300,000 or less, or 1,000,000 or less. The weight-average molecular weight of the water-soluble polymer can be measured as a value in terms of polyethylene glycol using gel permeation chromatography (GPC).

A lower limit value of a concentration of the water-soluble polymer in the post-CMP cleaning composition may be 0.1 g/L or more, 0.5 g/L or more, or 1.0 g/L or more. In addition, an upper limit value of the concentration of the water-soluble polymer in the post-CMP cleaning composition may be 5.0 g/L or less, 3.0 g/L or less, or 2.0 g/L or less. In such a range, the post-CMP cleaning composition is easily desorbed from the surface of the polished objects to be polished after the rinse polishing.

When the post-CMP cleaning composition contains two or more types of the water-soluble polymers, the content of the water-soluble polymers means the total content thereof.

### (Water)

In the post-CMP cleaning composition according to the present embodiment, the water has a function of dispersing or dissolving each component such as the water-soluble polymer, the surfactant, and other additives. In addition, from the viewpoint of preventing water from inhibiting the action of other components or contamination of the polished objects to be polished, it is preferable to use water containing as few impurities as possible. Specifically, pure water or ultrapure water, from which impurity ions have been removed with an ion exchange resin and contaminants have been removed through a filter, or distilled water is preferable.

### (pH Adjuster)

A pH of the post-CMP cleaning composition according to the present embodiment is not particularly limited, but a lower limit of the pH may be 1 or more, 2 or more, 3 or more, or 4 or more. In addition, an upper limit value of the pH may be 12 or less, 11 or less, 10 or less, 9 or less, 8 or less, 7 or less, or 6 or less. In such a range, it is possible to prevent deterioration of consumable parts such as a polishing machine and a polishing pad in contact with the polishing machine, and generation of residues and scratches due to the deterioration. In addition, the pH of the post-CMP cleaning composition can be confirmed with a pH meter.

The pH of the post-CMP cleaning composition may be adjusted using a pH adjuster. The pH adjuster is not particularly limited, and a known pH adjuster used in the field of post-CMP cleaning composition can be used. As the pH adjuster, a known acid, base, salt thereof, or the like can be used.

Examples of the acid as the pH adjuster include an organic acid and an inorganic acid. Specific examples of the organic acid as the pH adjuster include carboxylic acids such as formic acid, acetic acid, propionic acid, butyric acid, valeric acid, caproic acid, enanthic acid, caprylic acid, pelargonic acid, capric acid, lauric acid, myristic acid, palmitic acid, margaric acid, stearic acid, oleic acid, linoleic acid, linolenic acid, arachidonic acid, docosahexaenoic acid, eicosapentaenoic acid, lactic acid, malic acid, citric acid, benzoic acid, phthalic acid, isophthalic acid, terephthalic acid, salicylic acid, mellitic acid, cinnamic acid, oxalic acid, malonic acid, succinic acid, glutaric acid, adipic acid, fumaric acid, maleic acid, aconitic acid, amino acid, anthranilic acid, and sulfonic acid and organic phosphonic acid. Specific examples of the inorganic acid include nitric acid, carbonic acid, hydrochloric acid, phosphoric acid, hypophosphorous acid, phosphorous acid, phosphonic acid, boric acid, hydrofluoric acid, orthophosphoric acid, pyrophosphoric acid, polyphosphoric acid, metaphosphoric acid, and hexametaphosphoric acid.

Examples of the base as the pH adjuster include an alkali metal hydroxide or a salt thereof, an alkaline earth metal hydroxide or a salt thereof, a quaternary ammonium hydroxide or a salt thereof, ammonia, and amine. Specific examples of the alkali metal include potassium, sodium. Specific examples of the alkaline earth metal include calcium and strontium. Specific examples of the salt include a carbonate, a hydrogen carbonate, a sulfate, and an acetate. Furthermore, specific examples of the quaternary ammonium include tetramethylammonium, tetraethylammonium, and tetrabutylammonium.

Specific examples of the quaternary ammonium hydroxide compound include a quaternary ammonium hydroxide or a salt thereof; and specific examples thereof include tetramethylammonium hydroxide, tetraethylammonium hydroxide, and tetrabutylammonium hydroxide. Furthermore, specific examples of the amine include methylamine, dimethylamine, trimethylamine, ethylamine, diethylamine, triethylamine, ethylenediamine, monoethanolamine, N-(β-aminoethyl)ethanolamine, hexamethylenediamine, diethylenetriamine, triethylenetetramine, piperazine anhydrous, piperazine hexahydrate, 1-(2-aminoethyl)piperazine, N-methylpiperazine, and guanidine.

The pH adjuster may be used alone or in combination of two or more types thereof. In addition, as the pH adjuster, a synthetic product may be used, or a commercially available product may be used.

### (Other Additives)

The post-CMP cleaning composition according to the present embodiment may further contain a known additive such as abrasives, an oxidant, a thickener, a dispersing agent, a surface protector, a wetting agent, and a dissolving auxiliary agent, as long as the effect of the present invention is not impaired. A content of the above-described additive can be appropriately set according to the purpose of addition. However, since components other than the essential components of the post-CMP cleaning composition according to the embodiment of the present invention may cause the residue, it is desirable that the components other than the essential components are not contained as much as possible, and it is desirable that the content thereof is as small as possible.

### <Method for Producing Post-CMP Cleaning Composition>

A method for producing the post-CMP cleaning composition according to the present embodiment is not particularly limited. For example, the post-CMP cleaning composition according to the embodiment of the present invention can be obtained by stirring and mixing the water, the water-soluble polymer, the surfactant, and other additives as necessary. A temperature at the time of mixing the respective components is not particularly limited, but is preferably 10° C. or higher and 40° C. or lower; and the mixture may be heated in order to increase a dissolution rate. In addition, a mixing time is not particularly limited as long as the respective components are uniformly mixed.

### <Post-CMP Cleaning Method>

Another aspect of the present invention is a post-CMP cleaning method which is a method of performing post-CMP cleaning on polished objects to be polished which has a layer containing a silicon-containing material, using the above-described post-CMP cleaning composition, the method including bringing a surface of the polished objects to be polished which has the layer containing a silicon-containing material into contact with the post-CMP cleaning composition to form, on the surface of the polished objects to be polished which has the layer containing a silicon-containing material, a surface-treated layer containing water, a water-soluble polymer, and a surfactant. The surface-treated layer has an adsorption layer which is formed by adsorption of the surfactant over the surface of the polished objects to be polished which has the layer containing a silicon-containing material, in a case where the surface-treated layer is observed with an atomic force microscope, a restoring adhesion force that is a force acting between a probe of the atomic force microscope, which has a tip radius of curvature of 2 nm or more and 12 nm or less, and the surfactant in the surface-treated layer is more than 0 N/m and 0.07 N/m or less, and a surface roughness of a surface of the adsorption layer is more than 0 nm and 0.4 nm or less.

In the present specification, the post-CMP cleaning method refers to a method of reducing residues on the surface of the polished objects to be polished, and is a method of performing cleaning in a broad sense. According to the post-CMP cleaning method according to one aspect of the present invention, residues remaining on the surface of the polished objects to be polished can be effectively removed.

The post-CMP cleaning method according to one aspect of the present invention is performed by a method of bringing the post-CMP cleaning composition into direct contact with the surface of the polished objects to be polished. The post-CMP cleaning is not particularly limited, but is preferably performed by, for example, a rinse polishing treatment or a cleaning treatment. The rinse polishing treatment and the cleaning treatment are performed to remove contaminants on the surface of the polished objects to be polished, thereby obtaining a clean surface.

The rinse polishing treatment is performed on a polishing platen (platen) on which a polishing pad is attached after final polishing (finish polishing) is performed on objects to be polished, for the purpose of removing contaminants on the surface of the objects to be polished. At this time, by a frictional force (physical action) of the polishing pad and the action of the post-CMP cleaning composition, the surface-treated layer containing the water, the water-soluble polymer, and the surfactant is formed on the surface of the polished objects to be polished, and the residues on the surface of the polished objects to be polished is removed.

As a polishing machine, a general polishing machine having a holder which holds the objects to be polished, a motor of which the rotation speed is changeable, and a polishing platen on which a polishing pad can be attached can be used. As the polishing machine, any one of a single-sided polishing machine or a double-sided polishing machine may be used. In addition, when the CMP treatment and the rinse polishing treatment are performed using the same polishing machine, it is preferable that the polishing machine includes a discharge nozzle for the post-CMP cleaning composition according to one aspect of the present invention, in addition to a discharge nozzle for a polishing composition.

As the polishing pad, general nonwoven fabric, polyurethane, porous fluororesin, and the like can be used without particular limitation. It is preferable that the polishing pad is subjected to groove processing such that a polishing liquid is accumulated.

Rinse polishing conditions are not particularly limited, and can be appropriately set according to the characteristics of the post-CMP cleaning composition and the polished objects to be polished.

A pressure (polishing pressure) applied to the polished objects to be polished during the rinse polishing may be 0.5 psi (3.4 kPa) or more and 10 psi (68.9 kPa) or less.

A polishing time during the rinse polishing is not particularly limited. In general, the lower limit of the polishing time during the rinse polishing may be 5 seconds or more, 10 seconds or more, 15 seconds or more, or 20 seconds or more. In addition, from the viewpoint of efficiently removing the residues, the upper limit of the polishing time during the rinse polishing may be 180 seconds or less, 150 seconds or less, 120 seconds or less, or 100 seconds or less.

A rotation speed of the polishing platen during the rinse polishing is not particularly limited. In general, the lower limit of the rotation speed of the polishing platen during the rinse polishing may be 10 rpm (0.17 s⁻¹) or more, 20 rpm (0.33 s⁻¹) or more, or 30 rpm (0.5 s⁻¹) or more. In addition, the upper limit of the rotation speed of the polishing platen during the rinse polishing may be 500 rpm (8.3 s⁻¹) or less, 300 rpm (5 s⁻¹) or less, or 200 rpm (3.3 s⁻¹) or less.

A method of supplying the post-CMP cleaning composition in the rinse polishing is not particularly limited, and a method of continuously supplying (the one-way) the post-CMP cleaning composition with a pump or the like may be adopted. A supply amount of the post-CMP cleaning composition (a flow rate of the post-CMP cleaning composition) is not particularly limited as long as the entire polished objects to be polished is covered, but is generally 100 mL/min or more and 5,000 mL/min or less.

In the present specification, the cleaning treatment means a treatment of removing the residues on the surface of the polished objects to be polished by a chemical action of the post-CMP cleaning composition, which is performed in a state in which the polished objects to be polished is removed from the polishing platen.

Specific examples of the cleaning treatment include a treatment in which, after final polishing (finish polishing) treatment of the objects to be polished or after the final polishing, the rinse polishing treatment is performed, and then the polished objects to be polished is removed from the polishing platen and the polished objects to be polished is brought into contact with the post-CMP cleaning composition. In a contact state between the post-CMP cleaning composition and the polished objects to be polished, a unit which applies a frictional force (physical action) to the surface of the polished objects to be polished may be further used.

The cleaning treatment method, the cleaning treatment device, and the cleaning treatment conditions are not particularly limited, and known methods, devices, conditions, and the like can be appropriately used. The cleaning treatment method is not particularly limited, and examples thereof include a method of immersing the polished objects to be polished in the post-CMP cleaning composition and, as necessary, performing an ultrasonic treatment; and a method of bringing a cleaning brush and the polished objects to be polished into contact with each other in a state in which the polished objects to be polished is held, and rubbing a surface of the polished objects to be polished with a brush while supplying the post-CMP cleaning composition to a contact portion.

The cleaning with water may be carried out before or after the step of performing the post-CMP cleaning method according to one aspect of the present invention, or both before and after the step. Thereafter, water droplets attached to the surface of the polished objects to be polished may be removed and dried by a spin dryer, air blowing, or the like.

In the post-CMP cleaning method according to one aspect of the present invention, in a case of being observed with an atomic force microscope, a restoring adhesion force which is a force acting between a probe of the atomic force microscope, which has a tip radius of curvature of 2 nm or more and 12 nm or less, and the surfactant in the surface-treated layer formed on the surface of the polished objects to be polished which has the layer containing a silicon-containing material is more than 0 N/m and 0.07 N/m or less, and a surface roughness of a surface of the adsorption layer is more than 0 nm and 0.4 nm or less. The restoring adhesion force and the surface roughness are the same as those of the post-CMP cleaning composition described above.

Details of the method of measuring the restoring adhesion force and the surface roughness will be described in Examples later.

### EXAMPLES

Hereinafter, Examples and Comparative Examples of the present invention will be described, but the present invention is not limited to the examples shown below. Unless otherwise noted, “%” and “part” each mean “% by mass” and “part by mass”. In addition, in the examples shown below, unless otherwise noted, the operation was performed under conditions of room temperature (25° C.) and a relative humidity of 40% RH or more and 50% RH or less.

### <Preparation of Post-CMP Cleaning Composition>

### Example 1

A post-CMP cleaning composition of Example 1 was prepared by stirring and mixing polyvinyl alcohol (PVA; weight-average molecular weight (Mw): 10,000) as a water-soluble polymer, 3-[(3-cholamidopropyl)dimethylammonio]-1-propanesulfonic acid as a surfactant, 1-hydroxyethane-1,1-diphosphonic acid (HEDP) as a pH adjuster, and water (deionized water) as a solvent for 5 minutes. Here, a concentration of the water-soluble polymer in the post-CMP cleaning composition was set to 1.5 g/L, and a concentration of the surfactant was set to 0.5 g/L.

### Examples 2 to 12 and Comparative Examples 4 and 5

Post-CMP cleaning compositions of Examples 2 to 12 and Comparative Examples 4 and 5 were prepared in the same manner as in Example 1, except that the types of the water-soluble polymer and the surfactant were changed as shown in Table 1. Among the water-soluble polymers shown in Table 1, “PVP” indicates polyvinylpyrrolidone having a weight-average molecular weight of 45,000, and “HEC” indicates hydroxyethyl cellulose having a weight-average molecular weight of 1,400,000.

### Comparative Examples 1 to 3

Post-CMP cleaning compositions of Comparative Examples 1 to 3 were prepared in the same manner as in Example 1, except that the type of the water-soluble polymer was changed as shown in Table 1 and the surfactant was not added.

### Comparative Examples 6 and 7

Post-CMP cleaning compositions of Comparative Examples 6 and 7 were prepared in the same manner as in Example 1, except that the type of the surfactant was changed as shown in Table 1 and the water-soluble polymer was not added.

### Comparative Example 8

Deionized water was used as a post-CMP cleaning composition of Comparative Example 8.

### (Measurement of pH of Post-CMP Cleaning Composition)

A pH of each of the post-CMP cleaning compositions of Examples 1 to 12 and Comparative Examples 1 to 8 was confirmed with a pH meter (product name: LAQUA (registered trademark) manufactured by Horiba, Ltd.).

### <Preparation of Polished Objects to be Polished>

Polished objects to be polished after polishing by the following CMP step was prepared.

### (CMP Step)

As objects to be polished, a silicon wafer with a silicon nitride film (SiN film) having a diameter of 300 mm was prepared. A thickness of the silicon nitride film was 10,000 Å.

The silicon wafer with a silicon nitride film, which was prepared above, was polished using a polishing composition (formulation; colloidal silica (average primary particle diameter: 30 nm, average secondary particle diameter: 60 nm): 4%, 0.018% of a maleic acid aqueous solution having a concentration of 30%, solvent: water) under the following conditions and using the following device. After polishing the surface of the silicon wafer with a silicon nitride film, the obtained polished objects to be polished to be polished was removed from the polishing platen.
Polishing machine: FREX300E, a single-sided polishing machine for 300 mm CMP manufactured by Ebara Corporation
Polishing pad: H800 foamed polyurethane pad manufactured by FUJIBO HOLDINGS INC.
Polishing pressure: 2.0 psi (1 psi=6894.76 Pa)
Rotation speed of the polishing platen: 80 rpm
Rotation speed of head: 80 rpm
Supply of polishing composition: the one-way
Supply amount of polishing composition: 200 mL/min
Polishing time: 30 seconds

### (Rinse Polishing Step)

The obtained polished objects to be polished was installed on another polishing platen in the same polishing machine, and a rinse polishing treatment was performed on the surface of the polished objects to be polished using the post-CMP cleaning compositions of Examples 1 to 12 and Comparative Examples 1 to 8 under the following device and conditions.
Polishing machine: FREX300E, a single-sided polishing machine for 300 mm CMP manufactured by Ebara Corporation
Polishing pad: H800 foamed polyurethane pad manufactured by FUJIBO HOLDINGS INC.
Polishing pressure: 2.0 psi (1 psi=6894.76 Pa)
Rotation speed of the polishing platen: 60 rpm
Rotation speed of head: 60 rpm
Supply of post-CMP cleaning composition: in the one-way
Supply amount of post-CMP cleaning composition: 300 mL/min
Rinse polishing time: 10 seconds

### <Evaluation>

### (Measurement of Restoring Adhesion Force)

The rinse polished objects to be polished at the stage after the rinse polishing step was cut out into a square of 30 mm×30 mm. For the cut-out rinse polished objects to be polished, a restoring adhesion force acting between a probe of an atomic force microscope and the surfactant contained in the post-CMP cleaning composition was measured. The measurement results are shown in Table 1.

For the measurement of the restoring adhesion force, PeakForce QNM and Ringing mode of the atomic force microscope were used. In this mode, first, the probe of the atomic force microscope was pushed into the surface of the rinse polished objects to be polished, and then the probe was quickly separated from the surface. At this time, by controlling a deflection amount of cantilever, the probe was not adhered to the surface of the rinse polished objects to be polished, but was in a state of being adhered to the surfactant. Thereafter, the probe was separated from the surface of the rinse polished objects to be polished to be polished, and the surfactant was also separated from the probe. By analyzing a signal of the damped oscillation of the cantilever between a state in which only the probe and the surfactant were adhered and a state in which the probe and the surfactant were separated, it was possible to measure the adhesion force, that is, the restoring adhesion force acting between the probe and the surfactant. Thereafter, by using the same material as the residue for the probe, the probe could be regarded as the residue. Therefore, the measured restoring adhesion force represents the adhesive force acting between the residue and the surfactant, and as the value of the restoring adhesion force was smaller, the residue was released more easily from the surfactant.

The measuring device and measurement conditions for the restoring adhesion force were as follows. The measurement was carried out in water adjusted to the same pH as each of Examples and Comparative Examples.
Measurement device: AFM-IR Dimension icon-IR manufactured by Bruker Japan Co., Ltd.
Probe: SCANASYST-FRUID+
Probe tip material: Si
Tip radius of curvature: 2 nm
Scanning frequency: 0.5 Hz
Scanning range: 100×100 nm

TABLE 1

| | Water-soluble | | | | | | | Restoring | roughness | Number |
|---|---|---|---|---|---|---|---|---|---|---|
| | polymer | | Surfactant | | | pH adjuster | | adhesion | Surface | of |
| | | Concentration | | | Concentration | Compo- | | force | Ra | residues |
| | Type | [g/L] | Type | Ionic | [g/L] | nent | pH | [N/m] | [nm] | [pieces] |
| Ex. 1 | PVA | 1.5 | 3-[(3- | Amphoteric | 0.50 | HEDP | 4.5 | 0.028 | 0.13 | 67 |
| | | | Colamidopropyl)dimethylammonio]- | | | | | | | |
| | | | 1-propanesulfonic acid | | | | | | | |
| Ex. 2 | PVP | 1.5 | Dodecyldimethyl(3- | Amphoteric | 0.50 | HEDP | 4.5 | 0.030 | 0.15 | 75 |
| | | | sulfopropyl)ammonium | | | | | | | |
| | | | hydroxide | | | | | | | |
| Ex. 3 | HEC | 1.5 | Domiphen bromide | Cationic | 0.50 | HEDP | 4.5 | 0.069 | 0.35 | 197 |
| Ex. 4 | PVA | 1.5 | Decyltrimethylammonium | Cationic | 0.50 | HEDP | 4.5 | 0.062 | 0.31 | 180 |
| | | | bromide | | | | | | | |
| Ex. 5 | PVP | 1.5 | 1-Dodecylpyridinium chloride | Cationic | 0.50 | HEDP | 4.5 | 0.061 | 0.34 | 191 |
| Ex. 6 | HEC | 1.5 | Benzyldecyl | Cationic | 0.50 | HEDP | 4.5 | 0.067 | 0.30 | 173 |
| | | | dimethylammonium bromide | | | | | | | |
| Ex. 7 | PVA | 1.5 | Hexaethylene glycol dodecyl | Nonionic | 0.50 | HEDP | 4.5 | 0.048 | 0.13 | 148 |
| | | | ether | | | | | | | |
| Ex. 8 | PVP | 1.5 | Polyethylene glycol mono-4- | Nonionic | 0.50 | HEDP | 4.5 | 0.047 | 0.11 | 129 |
| | | | nonylphenyl ether (n = | | | | | | | |
| | | | approximately 18) | | | | | | | |
| Ex. 9 | HEC | 1.5 | Monopalmitin | Nonionic | 0.50 | HEDP | 4.5 | 0.046 | 0.14 | 122 |
| Ex. 10 | PVA | 1.5 | Bis(2-ethylhexyl) sulfosuccinate | Anionic | 0.50 | HEDP | 4.5 | 0.034 | 0.19 | 79 |
| | | | sodium salt | | | | | | | |
| Ex. 11 | PVP | 1.5 | Sodium monododecyl phosphate | Anionic | 0.50 | HEDP | 4.5 | 0.038 | 0.21 | 92 |
| Ex. 12 | HEC | 1.5 | N-lauroylsarcosine sodium salt | Anionic | 0.50 | HEDP | 4.5 | 0.036 | 0.19 | 81 |
| Comp. | PVA | 1.5 | None | — | — | HEDP | 4.5 | 0.049 | 0.51 | 258 |
| Ex. 1 | | | | | | | | | | |
| Comp. | PVP | 1.5 | None | — | — | HEDP | 4.5 | 0.025 | 0.44 | 222 |
| Ex. 2 | | | | | | | | | | |
| Comp. | HEC | 1.5 | None | — | — | HEDP | 4.5 | 0.067 | 0.53 | 355 |
| Ex. 3 | | | | | | | | | | |
| Comp. | HEC | 1.5 | Ethanol | Nonionic | 0.50 | HEDP | 4.5 | 0.073 | 0.35 | 2993 |
| Ex. 4 | | | | | | | | | | |
| Comp. | PVP | 1.5 | 2-Butanol | Nonionic | 0.50 | HEDP | 4.5 | 0.330 | 0.47 | 4858 |
| Ex. 5 | | | | | | | | | | |
| Comp. | — | — | Ethanol | Nonionic | 0.50 | HEDP | 4.5 | 0.071 | 0.31 | 13545 |
| Ex. 6 | | | | | | | | | | |
| Comp | — | — | 2-Butanol | Nonionic | 0.50 | HEDP | 4.5 | 0.082 | 0.50 | 18451 |
| Ex. 7 | | | | | | | | | | |
| Comp. | — | — | — | — | — | — | — | 0.100 | 0.50 | 20563 |
| Ex. 8 | | | | | | | | | | |

### (Measurement of Surface Roughness of Surface of Adsorption Layer)

The rinse polished objects to be polished to be polished was cut into a square of 30 mm×30 mm, and a surface roughness of the rinse polished objects to be polished to be polished was evaluated using an atomic force microscope. Specifically, a 100 nm square range on a substrate was scanned with the atomic force microscope, and an arithmetic average roughness (Ra) was measured. The measurement results are shown in Table 1.

The measuring device and measurement conditions for the surface roughness were as follows. The measurement was carried out in water adjusted to the same pH as each of Examples and Comparative Examples.
Measurement device: AFM-IR Dimension icon-IR manufactured by Bruker Japan Co., Ltd.
Probe: SCANASYST-FRUID+
Probe tip material: Si
Tip radius of curvature: 2 nm
Scanning frequency: 0.5 Hz
Scanning range: 100×100 nm

### (Measurement of Number of Residues)

Using an optical inspection machine Surfscan (registered trademark) SP5 manufactured by KLA-Tencor Corporation, the number of residues having a diameter of 65 nm or more, remaining on the surface of the rinse polished objects to be polished to be polished subjected to the cleaning treatment in the above-described cleaning step, was measured. A section of an outer peripheral portion of 5 mm in the rinse polished objects to be polished to be polished after the cleaning treatment was excluded from the measurement target. The results are shown in Table 1.

As shown in Table 1, in Examples 1 to 12, the number of residues remaining on the surface of the rinse polished objects to be polished to be polished after the cleaning treatment was less than 200; and in Comparative Examples 1 to 8, the number of residues was 200 or more. From this, it was found that the post-CMP cleaning compositions of Examples 1 to 12 had a higher residue removal ability than the post-CMP cleaning compositions of Comparative Examples 1 to 8.

From the results of Examples 1 to 12 and Comparative Examples 1 to 8, it was found that, when the post-CMP cleaning composition contained both the water-soluble polymer and the surfactant, the restoring adhesion force was more than 0 N/m and 0.07 N/m or less, and the surface roughness was more than 0 nm and 0.40 nm or less, the residues remaining on the surface of the polished objects to be polished to be polished could be effectively removed.

In addition, for example, the present invention can adopt the following configuration.

[1] A post-CMP cleaning composition used for cleaning polished objects to be polished to be polished as objects to be polished, which has been subjected to a chemical mechanical polishing (CMP), the post-CMP cleaning composition containing:
water;
a water-soluble polymer; and
a surfactant,
in which, when a surface of the polished objects to be polished to be polished is covered with the post-CMP cleaning composition, in a case where the surface is observed with an atomic force microscope, a restoring adhesion force which is a force acting between a probe of the atomic force microscope, which has a tip radius of curvature of 2 nm or more and 12 nm or less, and the surfactant is more than 0 N/m and 0.07 N/m or less, and
a surface roughness of an adsorption layer which is formed by adsorption of the surfactant over the surface of the polished objects to be polished is more than 0 nm and 0.4 nm or less.

[2] The post-CMP cleaning composition according to [1], further containing a pH adjuster.

[3] The post-CMP cleaning composition according to [1] or [2], in which the water-soluble polymer is at least one selected from the group consisting of polyvinyl alcohol, polyvinylpyrrolidone, and hydroxyethyl cellulose.

[4] The post-CMP cleaning composition according to any one of [1] to [3], in which the surfactant is at least one selected from the group consisting of 3-[(3-cholamidopropyl)dimethylammonio]-1-propanesulfonic acid, dodecyldimethyl(3-sulfopropyl)ammonium hydroxide, domiphen bromide, decyltrimethylammonium bromide, 1-dodecylpyridinium chloride, benzyldodecyl dimethylammonium bromide, hexaethylene glycol monododecyl ether, polyethylene glycol mono-4-nonylphenyl ether, monopalmitin, bis(2-ethylhexyl) sulfosuccinate sodium salt, sodium monododecyl phosphate, and N-lauroylsarcosine sodium salt.

[5] A post-CMP cleaning method of performing post-CMP cleaning on polished objects to be polished which has a layer containing a silicon-containing material, using the post-CMP cleaning composition according to any one of [1] to [4], the post-CMP cleaning method including:
bring a surface of the polished objects to be polished which has the layer containing a silicon-containing material into contact with the post-CMP cleaning composition to form, on the surface of the polished objects to be polished which has the layer containing a silicon-containing material, a surface-treated layer containing the water, the water-soluble polymer, and the surfactant,
in which the surface-treated layer has an adsorption layer which is formed by adsorption of the surfactant over the surface of the polished objects to be polished which has the layer containing a silicon-containing material,
in a case where the surface-treated layer is observed with an atomic force microscope, a restoring adhesion force which is a force acting between a probe of the atomic force microscope, which has a tip radius of curvature of 2 nm or more and 12 nm or less, and the surfactant in the surface-treated layer is more than 0 N/m and 0.07 N/m or less, and
a surface roughness of a surface of the adsorption layer is more than 0 nm and 0.4 nm or less.

1. A post-CMP cleaning composition used for cleaning polished objects to be polished as objects to be polished, which has been subjected to a chemical mechanical polishing (CMP), the post-CMP cleaning composition containing:
water;
a water-soluble polymer; and
a surfactant,
wherein, when a surface of the polished objects to be polished is covered with the post-CMP cleaning composition, in a case where the surface is observed with an atomic force microscope, a restoring adhesion force which is a force acting between a probe of the atomic force microscope, which has a tip radius of curvature of 2 nm or more and 12 nm or less, and the surfactant is more than 0 N/m and 0.07 N/m or less, and
a surface roughness of an adsorption layer which is formed by adsorption of the surfactant over the surface of the polished objects to be polished is more than 0 nm and 0.40 nm or less.

2. The post-CMP cleaning composition according to claim 1, further containing:
a pH adjuster.

3. The post-CMP cleaning composition according to claim 1, wherein the water-soluble polymer is at least one selected from the group consisting of polyvinyl alcohol, polyvinylpyrrolidone, and hydroxyethyl cellulose.

4. The post-CMP cleaning composition according to claim 1, wherein the surfactant is at least one selected from the group consisting of 3-[(3-cholamidopropyl)dimethylammonio]-1-propanesulfonic acid, dodecyldimethyl(3-sulfopropyl)ammonium hydroxide, domiphen bromide, decyltrimethylammonium bromide, 1-dodecylpyridinium chloride, benzyldodecyl dimethylammonium bromide, hexaethylene glycol monododecyl ether, polyethylene glycol mono-4-nonylphenyl ether, monopalmitin, bis(2-ethylhexyl) sulfosuccinate sodium salt, sodium monododecyl phosphate, and N-lauroylsarcosine sodium salt.

5. A post-CMP cleaning method of performing post-CMP cleaning on polished objects to be polished which has a layer containing a silicon-containing material, using the post-CMP cleaning composition according to claim 1, the post-CMP cleaning method comprising:
bringing a surface of the polished objects to be polished which has the layer containing a silicon-containing material into contact with the post-CMP cleaning composition to form, on the surface of the polished objects to be polished which has the layer containing a silicon-containing material, a surface-treated layer containing the water, the water-soluble polymer, and the surfactant,
wherein the surface-treated layer has an adsorption layer which is formed by adsorption of the surfactant over the surface of the polished objects to be polished which has the layer containing a silicon-containing material,
in a case where the surface-treated layer is observed with an atomic force microscope, a restoring adhesion force which is a force acting between a probe of the atomic force microscope, which has a tip radius of curvature of 2 nm or more and 12 nm or less, and the surfactant in the surface-treated layer is more than 0 N/m and 0.07 N/m or less, and
a surface roughness of a surface of the adsorption layer is more than 0 nm and 0.4 nm or less.

6. The post-CMP cleaning composition according to claim 2, wherein the water-soluble polymer is at least one selected from the group consisting of polyvinyl alcohol, polyvinylpyrrolidone, and hydroxyethyl cellulose.

7. The post-CMP cleaning composition according to claim 2, wherein the surfactant is at least one selected from the group consisting of 3-[(3-cholamidopropyl)dimethylammonio]-1-propanesulfonic acid, dodecyldimethyl(3-sulfopropyl)ammonium hydroxide, domiphen bromide, decyltrimethylammonium bromide, 1-dodecylpyridinium chloride, benzyldodecyl dimethylammonium bromide, hexaethylene glycol monododecyl ether, polyethylene glycol mono-4-nonylphenyl ether, monopalmitin, bis(2-ethylhexyl) sulfosuccinate sodium salt, sodium monododecyl phosphate, and N-lauroylsarcosine sodium salt.

8. A post-CMP cleaning method of performing post-CMP cleaning on polished objects to be polished which has a layer containing a silicon-containing material, using the post-CMP cleaning composition according to claim 2, the post-CMP cleaning method comprising:
bringing a surface of the polished objects to be polished which has the layer containing a silicon-containing material into contact with the post-CMP cleaning composition to form, on the surface of the polished objects to be polished which has the layer containing a silicon-containing material, a surface-treated layer containing the water, the water-soluble polymer, and the surfactant,
wherein the surface-treated layer has an adsorption layer which is formed by adsorption of the surfactant over the surface of the polished objects to be polished which has the layer containing a silicon-containing material,
in a case where the surface-treated layer is observed with an atomic force microscope, a restoring adhesion force which is a force acting between a probe of the atomic force microscope, which has a tip radius of curvature of 2 nm or more and 12 nm or less, and the surfactant in the surface-treated layer is more than 0 N/m and 0.07 N/m or less, and
a surface roughness of a surface of the adsorption layer is more than 0 nm and 0.4 nm or less.
